(19) United States
(12) Patent Application Publication
(10) Pub. No.: US 2026/0243813 A1
(43) Pub. Date: Aug. 20, 2026

(54) SYSTEM AND METHOD FOR PROGRAMMABLE TESTING AND ANALYZING WIRE CONTROL TEST OBJECT

(71) Applicants: Hyundai Motor Company, Seoul (KR); Kia Corporation, Seoul (KR)

(72) Inventors: Kevin YANG, Yantai (CN); Peng LU, Yantai (CN); Harry QI, Yantai (CN)

(73) Assignees: Hyundai Motor Company, Seoul (KR); Kia Corporation, Seoul (KR)

(21) Appl. No.: 19/395,779

(22) Filed: Nov. 20, 2025

(30) Foreign Application Priority Data
Nov. 20, 2024 (CN) 202411661854.4

(51) Int. Cl. G01R 31/00

(52) U.S. Cl. CPC G01R 31/005

(57) ABSTRACT

In a system and method for programmable testing and analyzing wire control test objects, the system may include a user interface obtaining an input regarding a test case of the wire control test object; a processor communicatively connected to the user interface, parsing the obtained input regarding the test case of the wire control test object, and determining a target control command of the wire control test object based on the input and according to a predetermined control command matching rule and a predetermined control logic matching rule; and a communication interface receiving the target control command of the wire control test object determined by the processor, transmitting the target control command to the wire control test object, transmitting feedback information of the wire control test object to the processor, and performing real-time analysis and an evaluation on the performance of the wire control test object.

### CROSS-REFERENCE TO RELATED APPLICATION

The present application claims priority to and the benefit of Chinese Patent Application No. 202411661854.4 filed with the Chinese National Intellectual Property Administration on Nov. 20, 2024, the entire contents of which are incorporated herein by reference.

### BACKGROUND OF THE PRESENT DISCLOSURE

### Field of the Present Disclosure

The present disclosure relates to a field of a wire control test technology, and more particularly, to a system and a method for programmable testing and analyzing a wire control test object.

### Description of Related Art

Wire control testing is a test method to evaluate a performance and safety of a wire control system and is widely used in fields such as vehicles, mobile robots, and industrial robot arms.

For vehicles, wire control testing is a key to safe and stable operation of autonomous vehicles. During development and subsequent stages, conducting thorough testing of the wire control system of autonomous vehicles to verify reliability and stability is a necessary step to ensure safety. For mobile robots, wire control testing is also important because the motion of robot and navigation functions depends on precise wire control systems. For industrial robot arms, wire control testing focuses on ensuring the precision and repeatability of the robot arm's movements, as well as stability during high-speed movements or load changes, which are directly related to production efficiency and product quality.

Broadly speaking, wire control testing is a critical part of ensuring the reliability and safety of the wire control system, and a series of performance evaluations is used to ensure whether a wire control test object may operate normally in various environments while meeting relevant safety standards.

Currently, wire control systems typically involve writing various test script files to adapt to different test scenarios and demands. However, because the wire control logic has differences between different machine types and manufacturers, test engineers must tailor the test scripts for each unique test case, which not only increases workload but may also reduce the efficiency of the testing process. Additionally, the current testing methods often cannot achieve real-time analysis of the test data and cannot quickly find problems during the testing process, limiting their ability to detect and resolve problems in a timely manner.

In summary, there is a need to use a more intelligent and automated testing framework to improve the testing efficiency and ensure the integrity of wire control systems. These frameworks may include reusable test assemblies, modular designs, and advanced data analysis tools, allowing them to adapt to changing testing needs and accelerate problem diagnosis.

The above information disclosed in this Background section is only for enhancement of understanding of the background of the present disclosure, and therefore it may contain information that does not form the prior art which would already be known to a person of ordinary skill in the art.

### BRIEF SUMMARY

According to an exemplary embodiment of the present disclosure, a system and method for programmable testing and analyzing a wire control test object capable of solving defects and problems existing in the field of wire control testing are proposed. Embodiments of the present disclosure may improve test efficiency of the wire control test object through a simple plug configuration, and expand the test range to various types of the wire control systems, thereby realizing the adaptability and support for various types and different forms of wire control logic. At the same time, various exemplary embodiments of the present disclosure may provide real-time analysis and recording of data during a testing process, thereby enabling rapid evaluation of the wire control performance of the wire control test object and rapid identification of problems within the wire control test object.

According to an exemplary embodiment of the present disclosure, a system for programmable testing and analyzing a wire control test object is provided. The system may include a user interface configured to obtain an input regarding a test case of the wire control test object; a processor configured to be communicatively connected to the user interface, to parse the obtained input regarding the test case of the wire control test object, and to determine a target control command of the wire control test object based on the input and according to a predetermined control command matching rule and a predetermined control logic matching rule; and a communication interface configured to be communicatively connected to the processor and the wire control test object, respectively, to receive the target control command of the wire control test object determined by the processor, to transmit the target control command to the wire control test object, to transmit feedback information of the wire control test object to the processor so that the feedback information of the wire control test object is visualized, and to perform real-time analysis and an evaluation on the performance of the wire control test object.

The processor may include: a file acquisition and parsing unit configured to acquire a communication data definition file of the wire control test object, and to perform parsing on the acquired communication data definition file of the wire control test object in order to acquire information on a control command signal of the wire control test object and information on a control logic signal of the wire control test object; a control command abstract unit configured to map the acquired information on the control command signal of the wire control test object to a corresponding abstract control command message according to the predetermined control command matching rule, and to store a mapping relationship between the information on the control command signal of the wire control test object and the corresponding abstract control command message; a control logic abstract unit configured to map the acquired information on the control logic signal of the wire control test object to a corresponding abstract control logic message according to the predetermined control logic matching rule, and to store a mapping relationship between the information on the control logic signal of the wire control test object and the corresponding abstract control logic message; and a control command setting and transmission unit configured to obtain the input regarding the test case from the user interface, to parse the obtained input regarding the test case, to convert the input into the target control command of the wire control test object according to the predetermined control command matching rule and the predetermined control logic matching rule, and to transmit the target control command to the communication interface.

The system may include: a control command matching unit configured to be communicatively connected to the control command abstract unit, to store a predetermined control command matching rule mapping table, and to provide the stored predetermined control command matching rule mapping table to the control command abstract unit; and a control logic matching unit configured to be communicatively connected to the control logic abstract unit, to store a predetermined control logic matching rule mapping table, and to provide the stored predetermined control logic matching rule mapping table to the control logic abstract unit.

The communication interface may be connected to the processor via a first communication line, and the communication interface is connected to the wire control test object via a second communication line.

The communication interface, based on the target control command of the wire control test object being received from the processor, may be configured to convert the target control command into a format suitable for transmission through the second communication line to be transmitted to the wire control test object, and, based on the feedback information of the wire control test object being received, to convert the feedback information into a format suitable for transmission through the first communication line to be transmitted to the processor. The first communication line may include at least one of a USB-CAN cable and a USB-CANFD cable, and the second communication line may include at least one of a CAN bus, a CANFD bus, an Ethernet, and a LIN bus.

The wire control test object may include at least one of a vehicle, a mobile robot, and an industrial robot arm; the input regarding the test case of the wire control test object may include at least one of a property of the wire control test object, a test scenario of the wire control test object, and an expected control behavior; the communication data definition file of the wire control test object may include a DBC file; and the target control command may be set to an aperiodic signal or a periodic signal.

The information on the control command signal of the wire control test object includes at least one of a communication signal definition of the wire control test object, a numerical table, a message definition, and a communication compatibility; and the information on the control logic signal of the wire control test object may include at least one of an initialization logic, a handshaking logic, a mode switching logic, and a communication authentication logic of the wire control test object.

The system may include a storage device configured to store the feedback information of the wire control test object for offline analysis and evaluation of the performance of the wire control test object.

According to various exemplary embodiments of the present disclosure, a method for programmable testing and analyzing a wire control test object is provided. The method may include: obtaining input regarding a test case of the wire control test object through a user interface; parsing the obtained input regarding the test case of the wire control test object, and determining a target control command of the wire control test object based on the input according to a predetermined control command matching rule and a predetermined control logic matching rule through a processor; and receiving the determined target control command of the wire control test object, transmitting the target control command to the wire control test object, transmitting feedback information of the wire control test object to the processor so that the feedback information of the wire control test object is visualized, and performing real-time analysis and evaluation on the performance of the wire control test object through a communication interface

The method may further include: obtaining a communication data definition file of the wire control test object and parsing the obtained communication data definition file of the wire control test object to obtain information on a control command signal of the wire control test object and information on a control logic signal of the wire control test object; mapping the acquired information on the control command signal of the wire control test object to a corresponding abstract control command message according to the predetermined control command matching rule, and storing a mapping relationship between the information on the control command signal of the wire control test object and the corresponding abstract control command message; mapping the acquired information on the control logic signal of the wire control test object to a corresponding abstract control logic message according to the predetermined control logic matching rule, and storing a mapping relationship between the information on the control logic signal of the wire control test object and the corresponding abstract control logic message; and obtaining input regarding the test case from the user interface, parsing the obtained input regarding the test case, converting the input into the target control command of the wire control test object according to the predetermined control command matching rule and the predetermined control logic matching rule, and transmitting the target control command to the communication interface.

The method may further include: converting the target control command into a format suitable for transmission through a second communication line to be transmitted to the wire control test object based on receiving the target control command of the wire control test object from the processor by the communication interface; and converting the feedback information into a format suitable for transmission through a first communication line to be transmitted to the processor based on the feedback information of the wire control test object being received by the communication interface. The first communication line may include at least one of a USB-CAN cable and a USB-CANFD cable, and the second communication line may include at least one of a CAN bus, a CANFD bus, an Ethernet, and a LIN bus.

The wire control test object may include at least one of a vehicle, a mobile robot, and an industrial robot arm; the input regarding the test case of the wire control test object may include at least one of a property of the wire control test object, a test scenario of the wire control test object, and an expected control behavior; the communication data definition file of the wire control test object may include a DBC file; and the target control command may be set to an aperiodic signal or a periodic signal.

The method may further include storing the feedback information of the wire control test object for offline analysis and evaluation of the performance of the wire control test object.

According to various exemplary embodiments of the present disclosure, a computer-readable storage medium having computer instructions stored thereon is provided. When the computer instructions are executed by a processor, the following steps are realized: obtaining input regarding a test case of a wire control test object through a user interface; parsing the obtained input regarding the test case of the wire control test object, and determining a target control command of the wire control test object based on the input according to a predetermined control command matching rule and a predetermined control logic matching rule through a processor; and receiving the determined target control command of the wire control test object, transmitting the target control command to the wire control test object, transmitting feedback information of the wire control test object to the processor so that the feedback information of the wire control test object is visualized, and performing real-time analysis and evaluation on the performance of the wire control test object through a communication interface.

An exemplary embodiment of the present disclosure uses the above-described technical solution and has following beneficial effects.

Programmability: The system may be flexibly applied to different test demands and conditions through programmable methods, reducing the need to custom-build dedicated test equipment for each wire control test object, thereby not only reducing development and maintenance costs and but also enabling rapid adaptation to new test standards and technological changes.

Plug configuration: Through a simple plug configuration, corresponding test parameters and logic for different types of the wire control systems may be set, thereby improving test preparation efficiency.

Real-time analysis and recording: During the testing process, the system may provide real-time data collection, analysis, and recording functions, which helps to immediately evaluate the performance of the wire control test object and quickly track and resolve problems.

Problem identification: Through real-time data analysis, testers may quickly identify anomalies or failures in the wire control test object, thereby reducing problem diagnosis time.

Performance evaluation: By evaluating various performance indicators of the wire control test object, such as response time, accuracy, and stability, the wire control test object may always meet the specified performance requirements.

Wide applicability: It may be widely applied in different fields such as vehicles, mobile robots, and industrial robot arms, including various types of wire control test objects.

In short, by providing a highly efficient, flexible, and comprehensive test system, the test efficiency and quality of the wire control test object have been greatly improved. This is very important for ensuring reliability and safety of the wire control test object in actual applications, and at the same time, it helps reduce test cost and improve development efficiency.

Furthermore, effects that can be obtained or expected from embodiments of the present disclosure are directly or suggestively described in the following detailed description. That is, various effects expected from embodiments of the present disclosure will be described in the following detailed description.

### BRIEF DESCRIPTION OF THE DRAWINGS

Hereinafter, various exemplary embodiments of the present invention will be described with reference to the drawings. For a clear explanation, the same member in different drawings is represented by the same reference numeral. With respect to a point to be described, the drawings are just exemplary, and elements to be described are not drawn according to a particular ratio.

FIG. 1 is a block diagram of a system for programmable testing and analyzing a wire control test object according to an exemplary embodiment of the present disclosure.

FIG. 2 is a block diagram of a processor of a system for programmable testing and analyzing a wire control test object according to an exemplary embodiment of the present disclosure.

FIG. 3 is a flowchart of a method for programmable testing and analyzing a wire control test object according to an exemplary embodiment of the present disclosure.

FIG. 4 is a flowchart illustrating operation of a system for programmable testing and analyzing a wire control test object according to an exemplary embodiment of the present disclosure.

### DETAILED DESCRIPTION

Hereinafter, an exemplary embodiment of the present invention will be described in detail, and the exemplary embodiment of the present disclosure will be conducted on the premise of the technical measure of the present invention, and a detailed implementation method and a specific operation process are presented, but the protection scope of the present invention is not limited to the following exemplary embodiment of the present disclosure.

Hereinafter, an exemplary embodiment of the present invention will be described in detail with reference to the drawings.

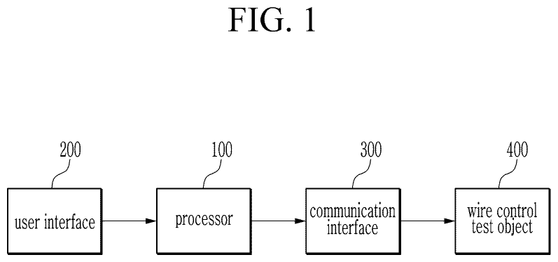

FIG. 1 is a block diagram of a system for programmable testing and analyzing a wire control test object according to an exemplary embodiment of the present disclosure.

Referring to FIG. 1, a system for programmable testing and analyzing a wire control test object according to an exemplary embodiment of the present disclosure may include a processor 100, a user interface 200, a communication interface 300, and a wire control test object 400.

The user interface 200 may be configured to obtain an input regarding test cases of the wire control test object 400. The processor 100 may be communicatively connected to the user interface 200, and may be configured to parse the input regarding the test case of the wire control test object 400, and determine a target control command of the wire control test object based on the inputs thereof and according to predetermined control command matching rules and predetermined control logic matching rules. The communication interface 300 may be communicatively connected to both the processor 100 and the wire control test object 400, and the communication interface 300 may be configured to receive the determined target control command of the wire control test object 400 from the processor 100, transmit the target control command to the wire control test object 400 and transmit feedback information of the wire control test object 400 to the processor 100, thereby making the feedback information of the wire control test object 400 visible and performing real-time analysis and evaluation on the performance of the wire control test object 400.

Below, the components of the system for the programmable testing and analyzing the wire control test objects are described in detail.

A user (e.g., a tester) sets various kinds of information and parameters related to the wire control test object 400 through the user interface 200 and uses them to simulate different test scenarios and conditions, thereby enabling effective testing to be conducted. The user may select or generate the wire control test object 400 through the user interface 200. This may be related to the specification of basic information such as the name, type, and properties of the wire control test object 400. The user may also set specific test objectives and expected results for the wire control test object 400 to ensure accuracy and reliability of the test.

Additionally, the user may configure other related settings for the test case. For example, the user may set control parameters such as the execution order of the test case, number of iterations, and a timeout time. That is, the target control command may be set as an aperiodic signal and/or a periodic signal. These parameters may help the user better control the control testing process, thereby improving the efficiency and accuracy of the tests.

The user may execute and monitor the test case through the user interface. Once the test begins, the user interface displays test progress and result information in real time. The user may regularly review and analyze this information to discover and resolve problems during the testing process in a timely manner. Additionally, the user may pause, stop, or restart the test as needed, enabling greater control over the testing process.

The user interface 200 according to an exemplary embodiment of the present disclosure may provide an intuitive and easy-to-use interface so that the user may conveniently configure and manage the test case of the wire control test object. Through the above interface, the user may flexibly define a test objective, input data, and related settings to better satisfy a testing need and improve testing efficiency.

The processor 100 converts the test case input provided by the user through the user interface 200 into a specific control command for the wire control test object.

The processor 100 receives input data from the user interface 200. The input data may include properties of the test object, parameters of a test scenario, expected control actions, etc. The processor 100 may parse these input data to accurately understand the test intention and needs of the user.

The processor 100 applies the predetermined control command matching rule and the predetermined control logic matching rule, and these rules define how to map the input data to the specific control command.

Once the target control command of the wire control test object is determined by the processor 100, the processor 100 transmits the target control command to the wire control test object 400 so that the wire control test object 400 is operated according to the control command.

During the test process, the processor 100 may also monitor the operating status and feedback information of the wire control test object 400 in real time. If any abnormality or error is found, the processor 100 immediately shows it to the user through the user interface 200 so that the user may understand the test situation in a timely manner and take a corresponding action.

The processer 100 acts as a key intermediary between the user interface 200 and the wire control test object 400. It is responsible for not only parsing the test case input of the user to generate the target control command, but also monitoring the test process and ensuring the smooth progress of the test. In this manner, the processor 100 provides a highly efficient and flexible wire control test solution to the user.

According to an exemplary embodiment of the present disclosure, the processor 100 may be integrated with the communication interface 300. This integration method forms an independent, comprehensive integrated terminal. In the test scenario, the processor 100 may establish a direct connection with the wire control test object to perform the wire control test.

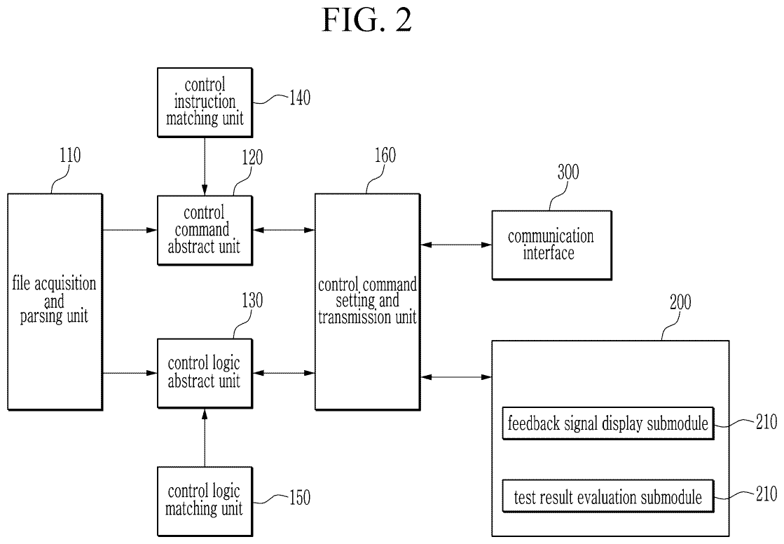

FIG. 2 is a block diagram of a processor of a system for programmable testing and analyzing a wire control test object according to an exemplary embodiment of the present disclosure. Referring to FIG. 2, the processor may include a file acquisition and parsing unit 110, a control command abstraction unit 120, a control logic abstraction unit 130, a control command matching unit 140, a control logic matching unit 150, and a control command setting and transmission unit 160.

The file acquisition and parsing unit 110 may be configured to acquire a communication data definition file of the wire control test object and to parse the acquired communication data definition file of the wire control test object in order to acquire information on the control command signal of the wire control test object and information on the control logic signal of the wire control test object.

The file acquisition and parsing unit 110 may acquire the communication data definition file of the wire control test object from a specified source or location. This file includes details and specifications related to the communication and control of the wire control test object. The file acquisition and parsing unit 110 may extract the information on the control command signal of the wire control test object by parsing the communication data definition file. This information includes a communication format message of the wire control test object—i.e., the specific format and structure by which the wire control test object transmits or receives messages. Understanding these formats and structures is crucial for accurately generating and parsing the control command.

For example, if the wire control test object is a vehicle, the communication data definition file is a database CAN (DBC) file, which is a file for defining the format of the vehicle CAN communication and includes all important information such as signal definitions, numerical tables, message definitions, communication compatibility, and fault diagnosis required for CAN bus communication. The DBC file is typically provided by vehicle manufacturers or system integrators to ensure communication compatibility and accuracy between the different wire control test objects and wire control test systems.

Additionally, the file acquisition and parsing unit 110 may extract the information on the control logic signal of the wire control test object. This information includes the logic flow in different situations of the test object. For example, an initialization logic defines an initialization process of the test object when it is started; a handshaking logic defines how the test object establishes a connection and synchronization with the wire control test system; a mode switching logic defines how the test object switches between different operating modes; and a communication authentication logic defines the reliability and validity of the communication between the test object and the wire control test system. Through the parsing of this control logic signal information, better design and implementation of the wire control system test may be performed, thereby ensuring system safety and reliability.

The file acquisition and parsing unit 110 parses the communication data definition file and acquires the above-mentioned important information to generate an accurate control command and realize precise control over the wire control test object. At the same time, this critical information helps the processing unit better understand the behavior and performance of the test object, thereby designing and executing test cases more effectively.

The control command abstract unit 120 may be configured to map information on the control command signal of the acquired wire control test object into a corresponding abstract control command message according to a predetermined control command matching rule. The control logic abstract unit 130 can be configured to map information on the control logic signal of the acquired wire control test object into a corresponding abstract control logic message according to the predetermined control logic matching rule.

The process involves matching the specific control signal and control logic of the wire control test object with a predefined abstract control signal and abstract control logic. Through the parsing and matching process, the different control logic and control signals of the various wire control test objects may be standardized into a unified control interface and signal. This enables control of a different wire control target by using a universal control signal, thereby realizing the versatility and wide range of the wire control test.

In order to realize the above-described mapping, the control command matching unit 140 and the control logic matching unit 150 store a predetermined control command matching rule mapping table and control logic matching rule mapping table. These mapping tables include the rules necessary to ensure that the signal information may be parsed and converted accurately. For example, Abstract_Acceleration represents an abstract acceleration control signal, and Abstract_Steering represents an abstract steering angle control signal.

Specifically, the control command matching unit 140 can be communicatively connected to the control command abstraction unit 120. The control command matching unit 140 stores the predetermined control command matching rule mapping table and provides the stored predetermined control command matching rule mapping table to the control command abstract unit 120. The control logic matching unit 150 may be communicatively connected to the control logic abstraction unit 130. The control logic matching unit 150 stores the predetermined control logic matching rule mapping table and provides the stored predetermined control logic matching rule mapping table to the control logic abstract unit 130.

According to an exemplary embodiment of the present disclosure, wire control testing of the different wire control test objects may be supported. For the different wire control test objects, only a programming configuration for the DBC file of the wire control test object and the control protocol tailored to the different test scenarios of the tester is required, so they may be quickly adapted to the different test objects. This design makes wire control testing more flexible and scalable, and also improves the test efficiency and accuracy at the same time.

The control command setting and transmission unit 160 may be configured to obtain the input regarding the test case from the user interface, parse the obtained input regarding the test case, and convert the input into the target control command of the wire control test object according to the predetermined control command matching rule and the predetermined control logic matching rule. That is, the control command setting and transmission unit 160 may be configured to convert the input abstract control command message and abstract control logic message into the target control command suitable for the wire control test object, and transmit the target control command to the communication interface 300.

According to an exemplary embodiment of the present disclosure, the target control command may be set as an aperiodic signal and/or a periodic signal. For example, the Abstract_Acceleration of the abstract acceleration control signal and the Abstract_Steering of the abstract steering angle control signal may be set to a sinusoidal signal, a periodic step signal, or a single step signal. Additionally, the width and period of the periodic signal may be set to satisfy various test requirements. This includes setting the period and width of the sinusoidal wave signal, the period and width of the step signal, and generating self-defined signals by using user-defined functions.

The sinusoidal periodic signal may be set as shown in Equation (1). Here, A is the width of the sinusoidal signal, T is the period of the sinusoidal signal, t is the time variable, and φ is the initial phase angle.

$$y = f ( t ) = Asin ( 2 π / T * t + φ ) \qquad ( 1 )$$

The step period signal may be set as shown in Equation (2). Here, A is the width of the periodic step signal, T is the period of the step signal, and t is the time variable.

$$y = f ( t ) = 00 \leq t \leq T / 2$$

$$y = f ( t ) = A T / 2 \leq t \leq T 2$$

According to an exemplary embodiment of the present disclosure, the system for the programmable testing and analyzing the wire control test object may further include a storage device. The storage device may be configured to store the control signals and control logic of one or more previously configured wire control test objects. Additionally, the storage device may directly load previous configuration information when retesting the wire control test object of the same model. For new and unknown test objects, the control signals and control logic of the wire control test object may be obtained through an automatic parsing and programming configuration method, thereby realizing a universal wire control test method.

The storage device may be provided internally or externally to the processor and may include a non-volatile computer-readable recording medium. Examples of computer-readable recording media include hard disk drives (HDDs), solid-state drives (SSDs), silicon disk drives (SDDs), read-only memory (ROM), random access memory (RAM), CD-ROMs, magnetic tapes, floppy disks, and optical data storage devices.

Referring again to FIG. 1, the communication interface 300 according to an exemplary embodiment of the present disclosure acts as a communication mediator between the processor 100 and the wire control test object 400. The communication interface 300 may be connected to the processor 100 via a first communication line and receive the target control command from the processor 100. This command is generated by the processing unit 100 based on the test case inputs provided by the user interface 200 and is intended to instruct the wire control test object 400 to complete the specific operations and tasks. The communication between the communication interface 300 and the processor 100 may be implemented in a wired or wireless manner, and is specifically determined by the connection type and communication protocol between the communication interface 300 and the processor 100. According to an exemplary embodiment of the present disclosure, the first communication line may include a USB-CAN cable, a USB-CANFD cable, or the like, but the exemplary embodiment of the present disclosure is not limited thereto.

The communication interface 300 is connected to the wire control test object 400 via a second communication line. The communication interface 300 may transmit the target control command to the wire control test object 400 through the second communication line so that the wire control test object 400 may perform the specific operations and tasks. The communication between the communication interface 300 and the wire control test object 400 may be implemented in a wired or wireless manner, and is specifically determined by the connection type and communication protocol between the communication interface 300 and the wire control test object 400. According to an exemplary embodiment of the present disclosure, the second communication line may include a CAN bus, a CANFD bus, an Ethernet, a LIN bus, or the like, but the exemplary embodiment of the present disclosure is not limited thereto.

In an exemplary embodiment of the present disclosure, the communication interface 300 is a communication device that supports a CAN or a CANFD and is used for transmitting or receiving CAN messages. However, according to different embodiments, the communication interface 300 may be adjusted to support devices of different communication lines.

Additionally, the communication interface 300 is responsible for transmitting the feedback information of the wire control test object 400. This feedback information may include the status of the wire control test object, sensor data, execution results, etc., and is intended to reflect the performance and situation during the process of executing the target control command of the wire control test object. The communication interface 300 receives feedback information from the wire control test object 400 and then transmits the feedback information to the processor 100. The processor 100 may analyze and process such feedback information to evaluate the performance and test effectiveness of the wire control test object. For example, the processor may check whether the wire control test object has accurately executed the target control command and whether there are any deviations or errors.

Additionally, the processor 100 may visually display the feedback information of the wire control test object 400 to the user through the user interface 200. For example, real-time data such as position, speed, and acceleration of the wire control test object 400 may be displayed, or change curves and diagrams are created during the test process. In this way, the user may intuitively understand the performance and test process of the wire control test object 400, thereby better evaluating the test effect and making corresponding decisions.

Referring to FIG. 2, the user interface 200 may include a feedback signal display sub-module 210 and a test result evaluation sub-module 220. The feedback signal display sub-module (210) is responsible for extracting signal values to be visualized from the feedback signal of the vehicle and then dynamically creating the curves. The test result evaluation sub-module 220 is responsible for comparing the target value or state of the wire control test object with the actual response value or state and calculating the corresponding wire control test result.

The system for the programmable testing and analyzing the wire control test object according to an exemplary embodiment of the present disclosure not only supports an online real-time visualization and analysis of the test data, but also supports data encryption and storage, and is used for subsequent offline analysis and evaluation of the test data.

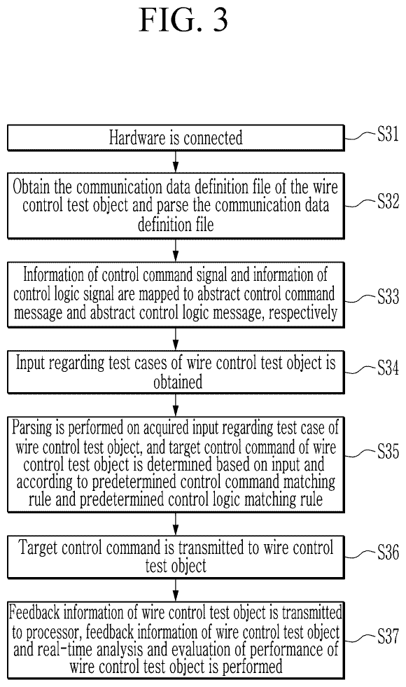

FIG. 3 is a flowchart of a method for programmable testing and analyzing a wire control test object according to an exemplary embodiment of the present disclosure.

In step (S31), hardware is connected. The communication interface 300 is connected to the processor 100 via a first communication line, and the wire control test object 400 is connected to the communication interface 300 via a second communication line.

In step (S32), in order to obtain information on the control command signal of the wire control test object 400 and information on the control logic signal of the wire control test object 400, a communication data definition file of the wire control test object 400 is obtained, and parsing is performed on the obtained communication data definition file of the wire control test object 400.

In step (S33), information on the control command signal of the acquired wire control test object 400 is mapped to the corresponding abstract control command message according to the predetermined control command matching rule and the predetermined control logic matching rule, and information on the control logic signal of the acquired wire control test object 400 is mapped to a corresponding abstract control logic message.

In step (S34), input regarding the test case of the wire control test object 400 is obtained.

In step (S35), parsing is performed on the input regarding the test case of the acquired wire control test object 400, and a target control command of the wire control test object 400 is determined based on the input and according to the predetermined control command matching rule and the predetermined control logic matching rule.

In step (S36), the target control command is transmitted to the wire control test object 400.

In step (S37), feedback information of the wire control test object 400 is transmitted to the processor 100, feedback information of the wire control test object 400 is visualized, and real-time analysis and evaluation of the performance of the wire control test object 400 are performed.

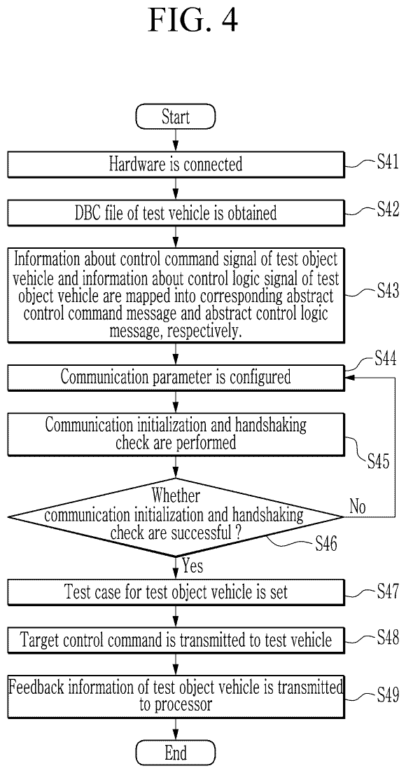

Hereinafter, the operation flow of the system for programmable testing and analyzing the wire control test object according to an exemplary embodiment of the present disclosure will be described using an example of a vehicle as the wire control test object 400 and the CAN communication as an in-vehicle communication method. FIG. 4 is an operational flow diagram of a system for programmable testing and analyzing a wire control test object according to an exemplary embodiment of the present disclosure.

Referring to FIG. 4, in step (S41), hardware is connected. The communication interface 300 is connected to the processor 100 via the USB-CANFD cable, and the vehicle under test is connected to the communication interface 300 via the CAN bus.

In step (S42), the DBC file of a test object vehicle is acquired, and the acquired DBC file is parsed to acquire information on the control command signal of the test object vehicle and information on the control logic signal of the test object vehicle.

In step (S43), according to the predetermined control command matching rule and the predetermined control logic matching rule, information on the control command signal of the acquired test object vehicle is mapped to the corresponding abstract control command message and information on the control logic signal of the acquired test object vehicle is mapped to the corresponding abstract control logic message.

In step (S44), communication parameters are configured. The communication parameters include configuring the transmission speed and channel of the CAN communication used in the CAN communication hardware. These communication parameters are set according to the actual hardware device and communication needs.

In step (S45), a communication initialization and a handshaking check are performed. Step (S45) is to ensure that the test terminal and the test object terminal may communicate normally. Initialization logic and handshaking logic may vary depending on different test objects, so they should be adjusted according to the actual situation.

In addition to the CAN bus communication, other communication methods such as Ethernet communication or LIN bus communication may be used as the in-vehicle communication method. Therefore, corresponding communication parameters and corresponding communication initialization and handshaking check are configured according to the different in-vehicle communication methods, and signal transmission is performed between the test terminal and the test object terminal to implement a remote test debugging scenario.

In step (S46), it is determined whether the communication initialization and the handshaking check are successful. If the communication initialization and the handshaking are successful, the process enters step (S47). If the communication initialization and the handshaking check fail, the process returns to step (S44) until the communication initialization and the handshaking check succeed.

In step (S47), a test case for the test object vehicle is set. A target control command according to a specific test case scenario is set. If required, control input values are configured, such as periodic sine waves, periodic step signals, or self-defined values.

Specifically, setting up the test case for the test object vehicle includes obtaining input regarding the test case for the test object vehicle, parsing the obtained input regarding the test case for the test object vehicle, and determining the target control command for the test object vehicle based on the input and according to the predetermined control command matching rule and the predetermined control logic matching rule.

In step (S48), a target control command is sent to the test object vehicle. That is, the configured target control command is transmitted to the test vehicle. For target control commands with different cycles, the transmission interval of each target control command may be set.

In step (S49), a feedback information of the test object vehicle is transmitted to the processor 100 so that the feedback information of the test object vehicle is visualized and the real-time analysis and evaluation of the performance of the test object vehicle is performed. For example, by plotting curves and analyzing data, the performance of the test vehicle is evaluated for parameters such as a wire control response delay, a steady-state error, and overshooting. According to an exemplary embodiment of the present disclosure, various visualization and data editing options may be supported to facilitate real-time analysis. Additionally, data may be stored for an offline analysis.

After completing the test requirements, each connection between the hardware components is disconnected.

The system and method according to an exemplary embodiment of the present disclosure realize automatic parsing of the DBC file of the test object vehicle, and provide the programming interface so that the specific control logic and communication protocol of each wire control target may be configured. Accordingly, different and independent control signals and control logic of the wire control test object may be aligned into a predefined, abstract, and general-purpose control signal framework. This provides unified and universal wire control test support for the different wire control test objects, thereby eliminating the need to modify and generate control signals and allowing control logic to be tailored to each individual wire control test object, simplifying wire control testing with this efficiency improvement.

Various embodiments of the present disclosure may not enumerate all possible combinations, but rather illustrate representative aspects of the present disclosure, and furthermore, the contents described in the various embodiments may be applied independently or in a combination of two or more.

While this invention has been described in connection with what is presently considered to be practical embodiments, it is to be understood that the present disclosure is not limited to the disclosed exemplary embodiments. On the contrary, it is intended to cover various modifications and equivalent claims as well as various alternatives and modifications thereof. It is intended that the scope of the present disclosure be defined by the Claims appended hereto and their equivalents.”

What is claimed is:

1. A system for programmable testing and analyzing a wire control test object, the system comprising:
a user interface obtaining input regarding a test case of the wire control test object;
a processor communicatively connected to the user interface, parsing the obtained input regarding the test case of the wire control test object, and determining a target control command of the wire control test object based on the input and according to a predetermined control command matching rule and a predetermined control logic matching rule; and
a communication interface communicatively connected to the processor and the wire control test object, respectively, receiving the target control command of the wire control test object determined by the processor, transmitting the target control command to the wire control test object, transmitting feedback information of the wire control test object to the processor so that the feedback information of the wire control test object is visualized, and performing real-time analysis and an evaluation on performance of the wire control test object.

2. The system of claim 1, wherein the processor comprises:
a file acquisition and parsing unit acquiring a communication data definition file of the wire control test object, and performing parsing on the acquired communication data definition file of the wire control test object in order to acquire information on a control command signal of the wire control test object and information on a control logic signal of the wire control test object;
a control command abstract unit mapping the acquired information on the control command signal of the wire control test object to a corresponding abstract control command message according to the predetermined control command matching rule, and storing a mapping relationship between the information on the control command signal of the wire control test object and the corresponding abstract control command message;
a control logic abstract unit mapping the acquired information on the control logic signal of the wire control test object to a corresponding abstract control logic message according to the predetermined control logic matching rule, and storing a mapping relationship between the information on the control logic signal of the wire control test object and the corresponding abstract control logic message; and
a control command setting and transmission unit obtaining the input regarding the test case from the user interface, to parse the obtained input regarding the test case, to convert the input into the target control command of the wire control test object according to the predetermined control command matching rule and the predetermined control logic matching rule, and transmitting the target control command to the communication interface.

3. The system of claim 2, further comprising:
a control command matching unit being communicatively connected to the control command abstract unit, storing a predetermined control command matching rule mapping table, and providing the stored predetermined control command matching rule mapping table to the control command abstract unit; and
a control logic matching unit being communicatively connected to the control logic abstract unit, storing a predetermined control logic matching rule mapping table, and providing the stored predetermined control logic matching rule mapping table to the control logic abstract unit.

4. The system of claim 1,
wherein the communication interface is connected to the processor via a first communication line, and the communication interface is connected to the wire control test object via a second communication line, and
wherein the communication interface, based on the target control command of the wire control test object being received from the processor, converts the target control command into a format suitable for transmission through the second communication line to be transmitted to the wire control test object, and, based on the feedback information of the wire control test object being received, converts the feedback information into a format suitable for transmission through the first communication line to be transmitted to the processor.

5. The system of claim 4,
wherein the first communication line comprises at least one of a USB-CAN cable and a USB-CANFD cable, and
wherein the second communication line comprises at least one of a CAN bus, a CANFD bus, an Ethernet, and a LIN bus.

6. The system of claim 1,
wherein the wire control test object comprises at least one of a vehicle, a mobile robot, and an industrial robot arm,
wherein the input regarding the test case of the wire control test object comprises at least one of a property of the wire control test object, a test scenario of the wire control test object, and an expected control behavior,
wherein the communication data definition file of the wire control test object comprises a DBC file, and
wherein the target control command is set to an aperiodic signal or a periodic signal.

7. The system of claim 2,
wherein the information on the control command signal of the wire control test object comprises at least one of a communication signal definition of the wire control test object, a numerical table, a message definition, and a communication compatibility, and
wherein the information on the control logic signal of the wire control test object comprises at least one of an initialization logic, a handshaking logic, a mode switching logic, and a communication authentication logic of the wire control test object.

8. The system of claim 1, further comprising:
a storage device storing the feedback information of the wire control test object for offline analysis and evaluation of the performance of the wire control test object.

9. A method for programmable testing and analyzing a wire control test object, the method comprising:
obtaining an input regarding a test case of the wire control test object through a user interface;
parsing the obtained input regarding the test case of the wire control test object, and determining a target control command of the wire control test object based on the input according to a predetermined control command matching rule and a predetermined control logic matching rule through a processor communicatively connected to the user interface; and
receiving the determined target control command of the wire control test object, transmitting the target control command to the wire control test object, transmitting feedback information of the wire control test object to the processor so that the feedback information of the wire control test object is visualized, and performing real-time analysis and evaluation on the performance of the wire control test object through a communication interface communicatively connected to the processor.

10. The method of claim 9, further comprising:
obtaining a communication data definition file of the wire control test object and parsing the obtained communication data definition file of the wire control test object to obtain information on a control command signal of the wire control test object and information on a control logic signal of the wire control test object;
mapping the acquired information on the control command signal of the wire control test object to a corresponding abstract control command message according to the predetermined control command matching rule, and storing a mapping relationship between the information on the control command signal of the wire control test object and the corresponding abstract control command message;
mapping the acquired information on the control logic signal of the wire control test object to a corresponding abstract control logic message according to the predetermined control logic matching rule, and storing a mapping relationship between the information on the control logic signal of the wire control test object and the corresponding abstract control logic message; and
obtaining an input regarding the test case from the user interface, parsing the obtained input regarding the test case, converting the input into the target control command of the wire control test object according to the predetermined control command matching rule and the predetermined control logic matching rule, and transmitting the target control command to the communication interface.

11. The method of claim 10, further comprising:
converting the target control command into a format suitable for transmission through a second communication line to be transmitted to the wire control test object based on receiving the target control command of the wire control test object from the processor by the communication interface; and
converting the feedback information into a format suitable for transmission through a first communication line to be transmitted to the processor based on the feedback information of the wire control test object being received by the communication interface.

12. The method of claim 11,
wherein the first communication line comprises at least one of a USB-CAN cable and a USB-CANFD cable, and
wherein the second communication line comprises at least one of a CAN bus, a CANFD bus, an Ethernet, and a LIN bus.

13. The method for programmable testing and analyzing the wire control test object of claim 9,
wherein the wire control test object comprises at least one of a vehicle, a mobile robot, and an industrial robot arm,
wherein the input regarding the test case of the wire control test object comprises at least one of a property of the wire control test object, a test scenario of the wire control test object, and an expected control behavior,
wherein the communication data definition file of the wire control test object comprises a DBC file, and
wherein the target control command is set to an aperiodic signal or a periodic signal.

14. The method of claim 9, further comprising:
storing the feedback information of the wire control test object for offline analysis and evaluation of the performance of the wire control test object.

15. A non-transitory computer-readable storage medium having computer instructions stored thereon and executed by a processor and configured for performing:
obtaining an input regarding a test case of a wire control test object through a user interface;
parsing the obtained input regarding the test case of the wire control test object, and determining a target control command of the wire control test object based on the input according to a predetermined control command matching rule and a predetermined control logic matching rule through the processor; and
receiving the determined target control command of the wire control test object, transmitting the target control command to the wire control test object, transmitting feedback information of the wire control test object to the processor so that the feedback information of the wire control test object is visualized, and performing real-time analysis and evaluation on performance of the wire control test object through a communication interface communicatively connected to the processor.

16. The computer-readable storage medium of claim 15, wherein the computer instructions is executed by the processor, for further performing:
obtaining a communication data definition file of the wire control test object and parsing the obtained communication data definition file of the wire control test object to obtain information on a control command signal of the wire control test object and information on a control logic signal of the wire control test object;
mapping the acquired information on the control command signal of the wire control test object to a corresponding abstract control command message according to the predetermined control command matching rule, and storing a mapping relationship between the information on the control command signal of the wire control test object and the corresponding abstract control command message;
mapping the acquired information on the control logic signal of the wire control test object to a corresponding abstract control logic message according to the predetermined control logic matching rule, and storing a mapping relationship between the information on the control logic signal of the wire control test object and the corresponding abstract control logic message; and
obtaining an input regarding the test case from the user interface, parsing the obtained input regarding the test case, converting the input into the target control command of the wire control test object according to the predetermined control command matching rule and the predetermined control logic matching rule, and transmitting the target control command to the communication interface.

17. The computer-readable storage medium of claim 15, wherein the computer instructions is executed by the processor, for further performing:
converting the target control command into a format suitable for transmission through a second communication line to be transmitted to the wire control test object based on receiving the target control command of the wire control test object from the processor by the communication interface; and
converting the feedback information into a format suitable for transmission through a first communication line to be transmitted to the processor based on the feedback information of the wire control test object being received by the communication interface.

18. The computer-readable storage medium of claim 17, wherein the computer instructions is executed by the processor, for further performing:
wherein the first communication line comprises at least one of a USB-CAN cable and a USB-CANFD cable, and
wherein the second communication line comprises at least one of a CAN bus, a CANFD bus, an Ethernet, and a LIN bus.

19. The computer-readable storage medium of claim 17, wherein the computer instructions is executed by the processor, for further performing:
wherein the wire control test object comprises at least one of a vehicle, a mobile robot, and an industrial robot arm,
wherein the input regarding the test case of the wire control test object comprises at least one of a property of the wire control test object, a test scenario of the wire control test object, and an expected control behavior,
wherein the communication data definition file of the wire control test object comprises a DBC file, and
wherein the target control command is set to an aperiodic signal or a periodic signal.

20. The computer-readable storage medium of claim 15, wherein the computer instructions is executed by the processor, for further performing:
storing the feedback information of the wire control test object for offline analysis and evaluation of the performance of the wire control test object.
